(19) United States
(12) Patent Application Publication
(10) Pub. No.: US 2004/0220765 A1
(43) Pub. Date: Nov. 4, 2004

(54) Method for communication with a test system for integrated circuits

(76) Inventor: Josef Gluch, Cary, NC (US)

Correspondence Address: SLATER & MATSIL, L.L.P., 17950 PRESTON RD, SUITE 1000, DALLAS, TX, 75252-5793, US

(21) Appl. No.: 10/788,602

(22) Filed: Feb. 27, 2004

(30) Foreign Application Priority Data
Feb. 28, 2003 (DE) 103 09 208.0

(51) Int. Cl. G06F 19/00; G01R 31/00

(52) U.S. Cl. 702/119

(57) ABSTRACT

In a test system for testing an integrated circuit device, a software program that receives instructions from a user and issues commands to the test system for testing the integrated circuit device in accordance with the user instructions is provided. The software program includes computer program code for receiving an instruction from the user, computer program code for generating a generic command based upon the user instruction, the generic command being independent of the test system that is being used to test the integrated circuit device, computer program code for translating the generic command into a test system specific command, computer program code for providing the test system specific command to the test system, and computer program code for receiving a test result from the test system, the test result being provided in response to the test system specific command and indicative of a result of a test performed on the integrated circuit device.

### TECHNICAL FIELD

The invention relates to a method for communication with a test system for integrated circuits.

### BACKGROUND

A method of communication with a test system is known, for example, from U.S. Pat. No. 6,304,095 B1, which describes a semiconductor measurement apparatus with the capability to change test criteria dynamically.

This document also describes the general configuration of a test system and the program procedure. A tester is represented by hardware suitable for generating test signals suitable for the integrated circuit to be tested, for receiving reaction signals from the integrated circuit to be tested, and for passing the reaction signals on for evaluation or for storing, in order to allow for fault evaluation.

The tester is in this case controlled by software at a level close to machine code, referred to in the following text as a low-level program. This low-level program is controlled by a core program which communicates with various test-specific, circuit-specific and user-specific program parts, for example with a test plan, a user interface or a measurement algorithm. The communication in this case comprises the generation of test commands which are converted in the low-level program into signals, and the reception of reactions which are produced by the low-level program from reaction signals.

The core program with these program parts comprises commands in a relatively high-level programming language, and is referred to in the following text as a high-level program.

Since the high-level program and at least the core program must in this case communicate with the low-level program, and the low-level program depends on the hardware of the tester, that is, it is equipment-specific, each test system necessarily has its own specific high-level program. This means that the high-level program often differs from one manufacturing company to another, or often even from one equipment generation to another. This has the disadvantage that the programmer of the test system has to relearn the high-level program for each equipment or each generation. Furthermore, the high-level program often does not correspond to the requirements for the specific test task.

### SUMMARY OF THE INVENTION

The preferred embodiment of the invention reduces the time required for production of operational readiness of test systems by using a high-level program which is essentially standard for different test systems.

The preferred embodiment of the invention provides an autonomous interface program, which is specific for the test system. This system is provided such that a high-level code is converted to one or more low-level codes, which correspond to the functionality of the high-level code. One or more low-level codes are converted to one or more high-level codes, which correspond to the functionality of the low-level code. The high-level program is linked to the low-level program exclusively via the interface program, and vice versa.

In this case, the high-level codes and the low-level codes may represent both program codes and data codes.

With this method, the high-level program is thus designed to be independent of the low-level program. All that is required is to produce specific interface programs in each case for test systems from different manufacturers or from different equipment generations. The high-level codes, which the interface program “understands,” can be designed independently of the respective test system.

One expedient refinement of the invention provides for the high-level program to have a supply of high-level codes independent of the test system. This makes it possible to provide a high-level program that has a standard user interface, independent of the test system that is used. After a single learning process, every operator then knows all of the high-level codes, or the most important high-level codes, and can thus make the test systems ready for operation in little time and with a low probability of errors.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 shows a schematic illustration of the communication with a test system for integrated circuits according to the prior art; and

FIG. 2 shows a schematic illustration of the communication according to the invention with a test system for integrated circuits.

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

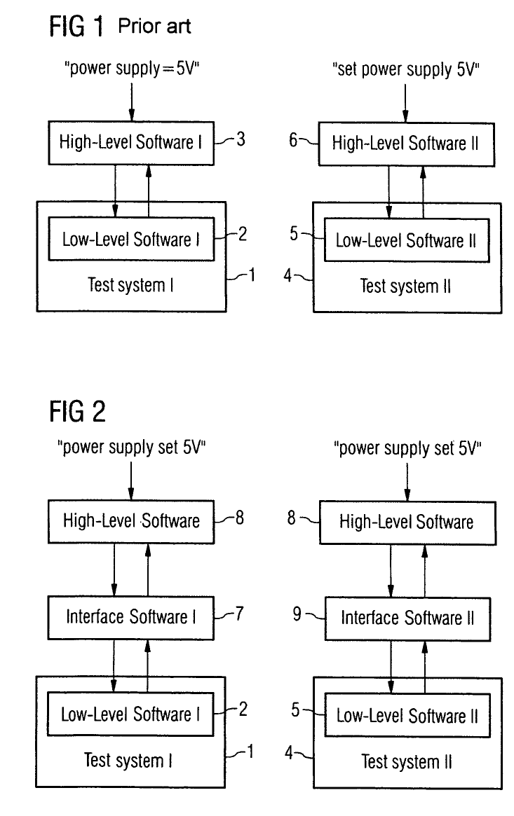

As illustrated in FIG. 1, a first low-level program 2 is implemented in a first test system 1. The first test system 1 is controlled by the first low-level program 2. The first low-level program 2 itself communicates with a first high-level program 3. In this case, a high-level code for the first high-level program 3 is converted by means of the first high-level program 3 to one or more low-level codes, which correspond to the functionality of the high-level code, for the first low-level program 2. Conversely, one or more low-level codes for the first low-level program 2 are converted in the first high-level program 3 to one or more high-level codes for the first high-level program 3, which correspond to the functionality of the low-level code.

A second low-level program 5 for a second test system 4 is implemented in the same way. The second test system 4 is controlled by the second low-level program 5. The second low-level program 5 itself communicates with a second high-level program 6. In this case, a high-level code for the second high-level program 6 is converted by the second high-level program 6 to one or more low-level codes, which correspond to the functionality of the high-level code, for the second low-level program 5. Conversely, one or more low-level codes for the second low-level program 5 are converted in the second high-level program 6 to one or more high-level codes for the second high-level program 6, which correspond to the functionality of the low-level code.

In one aspect, the invention relates to a method for communication with a test system for integrated circuits, in which commands of a high-level program are processed, and a low-level program produces test signals which are transmitted to the integrated circuit to be tested, and in which reaction signals from the integrated circuit are transmitted by the low-level program as reactions to the high-level program.

As can be seen from this, a first high-level program 3 is thus required specifically for the first test system 1, and a second high-level program 6 is required for the second test system 4. When making one test system and the other ready for operation, the operator has to change between at least two different software tools, which must be learned in advance. The support with suitable set-ups for the two or more test systems is also complex. In addition, the high-level program is often not completely matched to the test requirements. Adaptations and changes are, however, often feasible only to a very restricted extent.

The solution according to the preferred embodiment of the invention as illustrated in FIG. 2 now provides a specific first interface program 7 for the first test system 1 such that a high-level code for the standard high-level program 8 is converted to one or more low-level codes, which correspond to the functionality of the high-level code, for the first low-level program 2, and one or more low-level codes for the first low-level program 2 is or are converted to one or more high-level codes for the standard high-level program 8 which correspond to the functionality of the low-level code.

In the same way, a specific second interface program 9 is provided for the second test system 4, such that a high-level code for the standard high-level program 8 is converted to one or more low-level codes, which correspond to the functionality of the high-level code, for the second low-level program 5, and one or more low-level codes for the second low-level program 5 is or are converted to one or more high-level codes for the standard high-level program 8, which correspond to the functionality of the low-level code.

In principle, the standard high-level program 8 is linked to the first low-level program 2 exclusively via the first interface program 7, and vice versa. In the same way, the standard high-level program 8 is linked to the second low-level program 5 exclusively via the second interface program 9, and vice versa.

In this case, high-level codes and the low-level codes may represent both program codes and data codes.

This method therefore means that the standard high-level program 8 is independent of the respective low-level programs 2, 5. All that is required is to produce specific interface programs 7, 9 in each case for test systems from different manufacturers or for different equipment generations. The high-level codes which the interface program “understands” may in this case be independent of the respective test system.

One advantage of the preferred embodiment of the invention is that the functionality of the test systems 1, 4 can be used, and an interface on the “side” of the respective interface program 7, 9 which “faces” the standard high-level program 8 is available with the same functions on all test systems 1, 4. Building on these functions, a standard high-level program 8 can now be provided, which is the same for all the test systems 1, 4. It is thus possible to express in advance different commands for one and the same function, for example “power supply=5 V” or “set power supply 5 V” by means of one and the same command, for example “set power supply 5 V”.

Although the present invention and its advantages have been described in detail, it should be understood that various changes, substitutions and alterations can be made herein without departing from the spirit and scope of the invention as defined by the appended claims. Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. In a test system for testing an integrated circuit device, a software program that receives instructions from a user and issues commands to the test system for testing the integrated circuit device in accordance with the user instructions, the software program including:
computer program code for receiving an instruction from the user;
computer program code for generating a generic command based upon the user instruction, the generic command being independent of the test system that is being used to test the integrated circuit device;
computer program code for translating the generic command into a test system specific command;
computer program code for providing the test system specific command to the test system; and
computer program code for receiving a test result from the test system, the test result being provided in response to the test system specific command and indicative of a result of a test performed on the integrated circuit device.

2. The software program of claim 1 wherein the computer program code for receiving an instruction from the user and the computer program code for generating a generic command are located in a high-level program module, the high-level program module being usable with a plurality of different test systems without modification.

3. The software program of claim 2 wherein the computer program code for translating the generic command into a test system specific command is located in an interface software module and wherein the computer program code for providing the test system specific command to the test system and the computer program code for receiving a test result are located in a low-level program module, wherein the interface software module and the low-level software module are unique to a specific test system.

4. The software program of claim 3 wherein all communications between the high-level program module and the low-level program module are routed through the interface software module.

5. The software program of claim 3 wherein the interface software module is provided such that high-level code from the high-level program module is converted to one or more low-level codes that correspond to the functionality of the high-level code, and one or more low-level codes from the low-level program module are converted to one or more high-level codes that correspond to the functionality of the low-level code.

6. The software program of claim 1 wherein the computer program code for translating the generic command into a test system specific command is located in an interface software module and wherein the computer program code for providing the test system specific command to the test system and the computer program code for receiving a test result are located in a low-level software module, wherein the interface software module and the low-level software module are unique to a specific test system.

7. A method for communication with a test system for integrated circuits, in which commands of a high-level program are processed, and a low-level program produces test signals that are transmitted to the integrated circuit to be tested, and in which reaction signals from the integrated circuit are transmitted by the low-level program as reactions to the high-level program, characterized in that an autonomous interface program, which is specific for the test system, is provided such that one or more high-level codes are converted to one or more low-level codes that correspond to the functionality of the high-level code, and one or more low-level codes are converted to one or more high-level codes which correspond to the functionality of the low-level code, and in that the high-level program is linked to the low-level program exclusively via the interface program and the low-level program is linked to the high-level program exclusively via the interface program.

8. The method according to claim 7 wherein the high-level program has a supply of high-level codes that are independent of the test system.

9. In a test system for testing an integrated circuit device, a software program that receives instructions from a user and issues commands to a test system for testing the integrated circuit device in accordance with the user instructions, the test system including one or more pieces of test equipment, the software program including:
a high-level program including:
computer program code for receiving a user instruction from the user; and
computer program code for generating a generic command based upon the user instruction, the generic command being independent of the test system that is being used to test the integrated circuit device;
a low-level program including:
computer program code for interfacing with the test system by providing test commands to the test system and receiving test results from the test system;
wherein the low-level program is unique for each piece of test equipment in the test system;
an interface program including:
computer program code for translating the generic command from the high-level program into a test system specific command;
computer program code for providing the test system specific command to the low-level program;
computer program code for receiving a test result from the low-level program, the test result being indicative of a result of a test performed on the integrated circuit device based on the generic command; and
computer program code for providing the test result to the high-level program.

10. The software program of claim 9 wherein the high-level program is usable with a plurality of different test systems without modification.

11. The software program of claim 10 wherein all communications between the high-level program and the low-level program are routed through the interface program.

12. The software program of claim 10 wherein interface is unique to a specific test system.

13. The software program of claim 12 wherein all communications between the high-level program and the low-level program are routed through the interface program.

14. The software program of claim 9 wherein interface is unique to a specific test system.

15. The software program of claim 9 wherein all communications between the high-level program and the low-level program are routed through the interface program.

16. The software program of claim 9 wherein the interface further includes computer program code for converting one or more low-level codes from the low-level program to one or more high-level codes that correspond to the functionality of the one or more low-level codes.

17. The software program of claim 16 wherein the interface further includes computer program code for converting one or more high-level codes from the high-level program to one or more low-level codes that correspond to the functionality of the one or more high-level codes.
